(19) United States
(12) Patent Application Publication
(10) Pub. No.: US 2015/0263278 A1
(43) Pub. Date: Sep. 17, 2015

(54) MEMORY DEVICE

(71) Applicant: Kabushiki Kaisha Toshiba, Minato-ku (JP)

(72) Inventors: Hiroyuki ODE, Yokkaichi (JP); Takeshi YAMAGUCHI, Yokkaichi (JP); Shigeki KOBAYASHI, Kuwana (JP); Masaki YAMATO, Yokkaichi (JP); Yoshinori NAKAKUBO, Yokkaichi (JP); Takeshi TAKAGI, Yokkaichi (JP); Takayuki TSUKAMOTO, Yokkaichi (JP)

(73) Assignee: Kabushiki Kaisha Toshiba, Minato-ku (JP)

(21) Appl. No.: 14/490,938

(22) Filed: Sep. 19, 2014

Related U.S. Application Data
(60) Provisional application No. 61/952,628, filed on Mar. 13, 2014.

(51) Int. Cl. H01L 45/00; H01L 27/24

(52) U.S. Cl. CPC H01L 45/1246; H01L 27/2463; H01L 27/2436

(57) ABSTRACT

A memory device according to an embodiment, includes a selection element, a first interconnection provided in a first direction when viewed from the selection element and extending in the first direction, a plurality of second interconnections provided in a second direction crossing the first direction when viewed from the first interconnection and arranged in the first direction, a memory element provided between the first interconnection and the second interconnection, and a high resistance component connected between the selection element and the first interconnection and having a resistivity higher than a resistivity of the first interconnection and a resistivity of the second interconnection.

### CROSS-REFERENCE TO RELATED APPLICATIONS

This application is based upon and claims the benefit of priority from U.S. Provisional Patent Application 61/952,628, filed on Mar. 13, 2014; the entire contents of which are incorporated herein by reference.

### FIELD

Embodiments described herein relate generally to a memory device.

### BACKGROUND

In recent years, a cross-point memory device is proposed in which memory cells are two-dimensionally or three-dimensionally integrated. Besides, a resistance change element having plural levels of resistance values is proposed as the memory cell. Switching between resistance states and detection of the resistance states are performed by causing a current to flow through the memory cell, and writing and reading of data is performed by this. In the memory device as stated above, there is a case where a current control mechanism is required in order to adjust the amount of current flowing through the memory cell.

### BRIEF DESCRIPTION OF THE DRAWINGS

FIG. 1 is a perspective view illustrating a memory device of an embodiment;

FIG. 2 is a sectional view illustrating a periphery of a high resistance component of the memory device of the embodiment;

FIG. 3 is a graph illustrating I-V characteristics of respective materials, in which the horizontal axis indicates voltage and the vertical axis indicates current; and

FIG. 4 is a block diagram illustrating the memory device of the embodiment.

### DETAILED DESCRIPTION

A memory device according to an embodiment, includes a selection element, a first interconnection provided in a first direction when viewed from the selection element and extending in the first direction, a plurality of second interconnections provided in a second direction crossing the first direction when viewed from the first interconnection and arranged in the first direction, a memory element provided between the first interconnection and the second interconnection, and a high resistance component connected between the selection element and the first interconnection and having a resistivity higher than a resistivity of the first interconnection and a resistivity of the second interconnection.

Hereinafter, embodiments of the invention will be described with reference to the drawings.

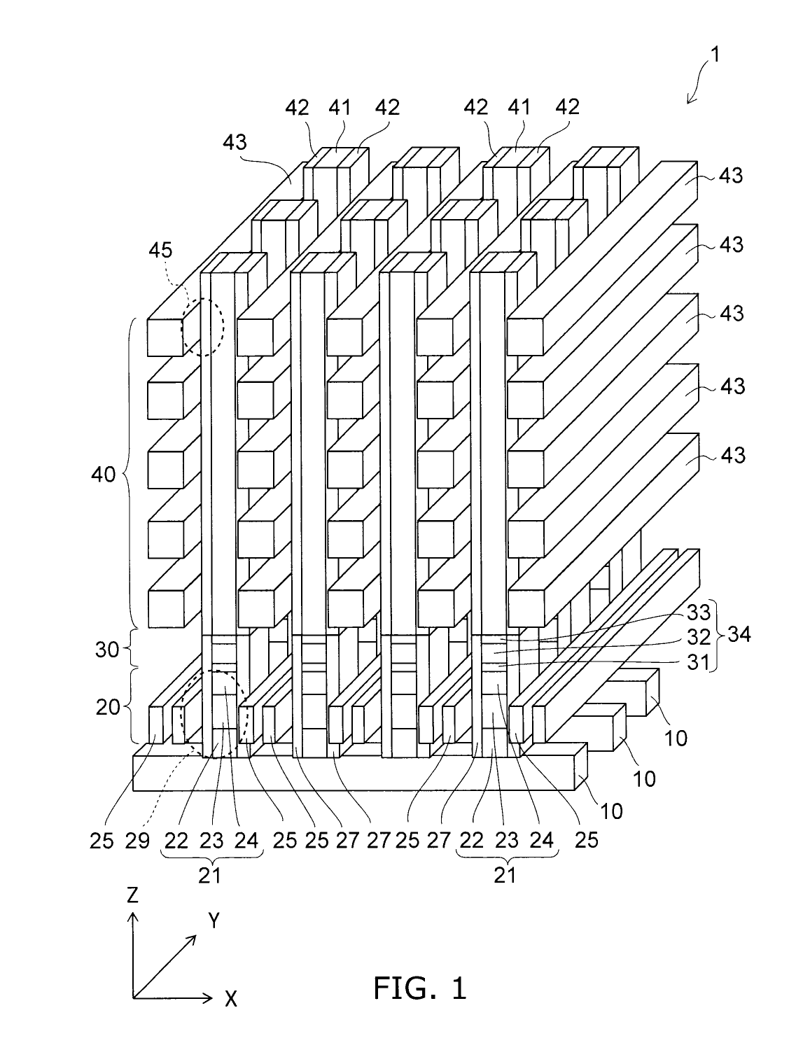

FIG. 1 is a perspective view illustrating a memory device of an embodiment.

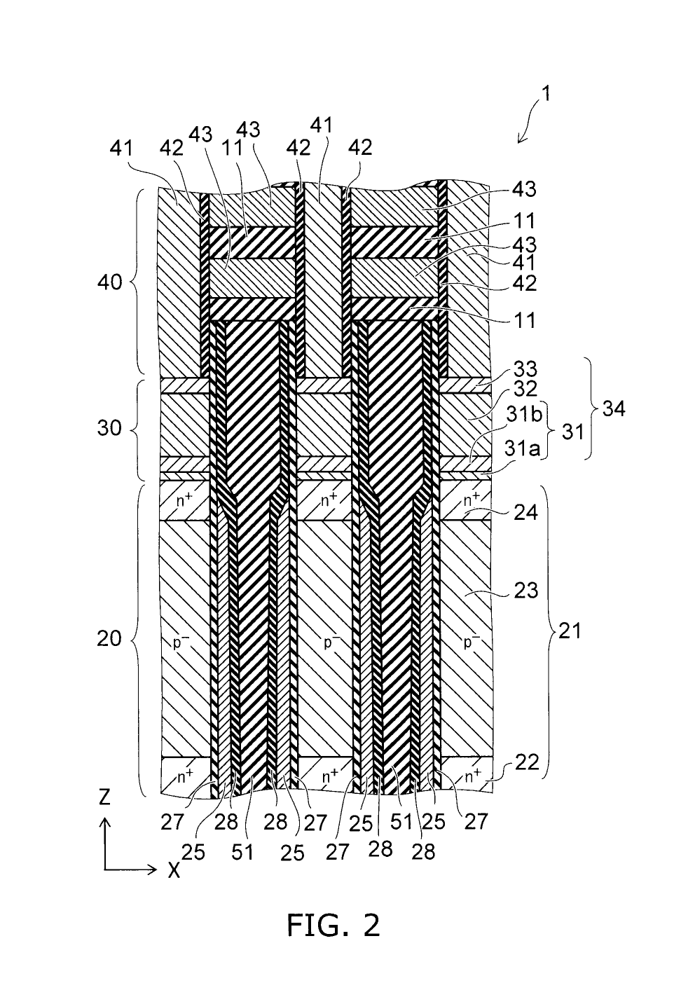

FIG. 2 is a sectional view illustrating a periphery of a high resistance component of the memory device of the embodiment.

The memory device of the embodiment is a vertical cross-point ReRAM (Resistance Random Access Memory).

First, a periphery of a memory unit of the memory device of the embodiment will be described.

Hereinafter, for convenience of description, an XYZ Cartesian coordinate system is adopted in the specification.

As shown in FIG. 1 and FIG. 2, in the memory device 1 of the embodiment, plural global bit lines 10 extending in an X-direction are provided. The plural global bit lines 10 are periodically arranged along a Y-direction. The global bit lines 10 are formed such that for example, an upper layer portion of a silicon substrate is divided by an element isolation insulator (not shown) or are formed such that an insulating film (not shown) is provided on a silicon substrate (not shown) and polysilicon is provided thereon.

An interconnection selection unit 20 is provided on the global bit lines 10, a current control unit 30 is provided thereon, and a memory unit 40 is provided thereon.

In the interconnection selection unit 20, plural semiconductor components 21 are provided. The plural semiconductor components 21 are arranged in a matrix form along the X-direction and the Y-direction, and each of the semiconductor components 21 extends in a Z-direction. The plural semiconductor components 21 arranged in a line along the X-direction are commonly connected to the one global bit line 10. In each of the semiconductor components 21, an n⁺-type portion 22, a p⁻-type portion 23 and an n⁺-type portion 24 are arranged in this order along the Z-direction from the lower side, that is, from the global bit line 10 side. Incidentally, the relation between the n-type and the p-type may be reversed.

The n⁺-type portions 22 and 24 are formed of, for example, silicon doped with an impurity as a donor. The p⁻-type portion 23 is formed of, for example, silicon doped with an impurity as an acceptor. The effective impurity concentration of the p⁻-type portion 23 is lower than the effective impurity concentration of the n⁺-type portions 22 and 24. The effective impurity concentration is the concentration of an impurity contributing to the conduction of a semiconductor material. For example, if both an impurity as a donor and an impurity as an acceptor are included in the semiconductor material, the effective impurity concentration is obtained by excluding the cancelled portion of the donor and the acceptor.

Two gate electrodes 25 extending in the Y-direction are provided between the adjacent semiconductor components 21 in the X-direction. The gate electrodes 25 are located at the same position in the Z-direction. The gate electrodes 25 are formed of, for example, polysilicon. When viewed from the X-direction, the gate electrode 25 overlaps an upper part of the n⁺-type portion 22, the whole of the p⁻-type portion 23 and a lower part of the n⁺-type portion 24.

A gate insulating film 27 made of, for example, silicon oxide is provided between the semiconductor component 21 and the gate electrode 25. For example, an n-channel TFT 29 is formed of the semiconductor component 21 including the n⁺-type portion 22, the p⁻-type portion 23 and the n⁺-type portion 24, the gate insulating film 27 and the gate electrode 25. Besides, liner films 28 made of, for example, silicon nitride are provided so as to cover the gate insulating films 27 and the gate electrodes 25.

In the current control unit 30, a barrier metal layer 31, a high resistance component 32 and a barrier metal layer 33 are stacked in this order just above each of the semiconductor components 21. Accordingly, stacked bodies 34 each including the barrier metal layer 31, the high resistance component 32 and the barrier metal layer 33 are equal in number to the number of the semiconductor components 21 and are arranged in a matrix form along the X-direction and the Y-direction. The gate insulating film 27 and the liner film 28 can extend onto the side surface of the stacked body 34 in the X-direction.

In the barrier metal layer 31, for example, a titanium (Ti) layer 31a and a titanium nitride (TiN) layer 31b are sequentially stacked from the lower layer side, and the titanium layer 31a contacts the n⁺-type portion 22 of the semiconductor component 21. The high resistance component 32 is formed of a material which is conductive and has a certain resistivity. The thickness of the high resistance component 32, that is, the length in the Z-direction is determined by a resistance value required for the high resistance component 32. The details of the high resistance component 32 will be described later. The barrier metal layer 33 is formed of, for example, titanium nitride (TiN).

The barrier metal layer 31, the high resistance component 32 and the barrier metal layer 33 can be formed such that after continuous films are formed by, for example, PVD (Physical Vapor Deposition), CVD (Chemical Vapor Deposition) or ALD (Atomic Layer Deposition), patterning is performed by lithography and RIE (Reactive Ion Etching).

Plural local bit lines 41 are provided in the memory unit 40. The plural local bit lines 41 are arranged in a matrix form along the X-direction and the Y-direction, and each of the local bit lines 41 extends in the Z-direction. A lower end of each of the local bit lines 41 contacts the barrier metal layer 33. Accordingly, the high resistance component 32 is connected between the semiconductor component 21 and the local bit line 41. The local bit lines 41 are formed of, for example, polysilicon.

Resistance change films 42 as memory elements are provided on two side surfaces of each of the local bit lines 41 in the X-direction. The resistance change films 42 are made of, for example, metal oxide. In the resistance change film 42, for example, when a voltage not lower than a certain value is applied, a filament is formed inside the resistance change film 42 and a low resistance state occurs. When a voltage of the reverse polarity is applied, the filament in the resistance change film 42 disappears, or the length of the filament becomes shorter than that in the low resistance state, and a high resistance state occurs.

Plural local word lines 43 are provided between the adjacent local bit lines 41 in the X-direction and between the resistance change films 42. The plural local word lines 43 are arranged in a matrix form along the X-direction and the Z-direction, and each of the local word lines 43 extends in the Y-direction. The local word lines 43 contact the resistance change films 42. Especially, the plural local word lines 43 arranged in a line along the Z-direction contact the common resistance change films 42. Each of the local word lines 43 contacts the resistance change films 42 at both sides in the X-direction.

A memory cell 45 is configured of the one local bit line 41, the one local word line 43 and a portion of the resistance change film 42 sandwiched therebetween. Accordingly, the plural memory cells 45 are connected in series to the one TFT 29. In the whole memory unit 40, the plural memory cells 45 are arranged in a three-dimensional matrix form along the X-direction, the Y-direction and the Z-direction.

Besides, in the memory device 1, interlayer insulating films 11 and 51 are provided so that the global bit lines 10, the semiconductor components 21, the gate electrodes 25, the gate insulating films 27, the liner films 28, the barrier metal layers 31, the high resistance components 32, the barrier metal layers 33, the local bit lines 41, the resistance change films 42 and the local word lines 43 are embedded.

Hereinafter, the characteristics of the high resistance component 32 will be described in detail.

The resistivity of the high resistance component 32 is higher than the resistivity of the global bit line 10, the resistivity of the local bit line 41 and the resistivity of the local word line 43, and is lower than the resistivity of the interlayer insulating films 11 and 51. More specifically, the resistivity of the high resistance component 32 is preferably higher than 0.01 Ω•cm.

The linearity of the resistance of the high resistance component 32 is higher than the linearity of the resistance of the insulating material. More specifically, a value (R_{1μA}/R_{10μA}) of a ratio of a resistance value R_{1μA} obtained when a current of 1 μA flows to a resistance value R_{10 μA} obtained when a current of 10 μA (micro ampere) flows through the one high resistance component 32 is 1 or more and less than 5. Incidentally, 1 μA is a typical value of a current flowing when forming is performed on the resistance change film 42, and 10 μA is a typical value of a current flowing when the resistance change film 42 is switched, that is, is set or reset.

The high resistance component 32 may be formed of, for example, metal nitride such as tantalum silicon nitride (TaSiN) or tantalum aluminum nitride (TaAlN), or may be formed of metal oxide such as titanium oxide (TiO) or tantalum oxide (TaO), or may be formed of silicon material such as polysilicon. Alternatively, the high resistance component may be a stacked film in which plural layers of these materials are stacked. For example, the high resistance component 32 is formed of Ta₂Si₃N₅.

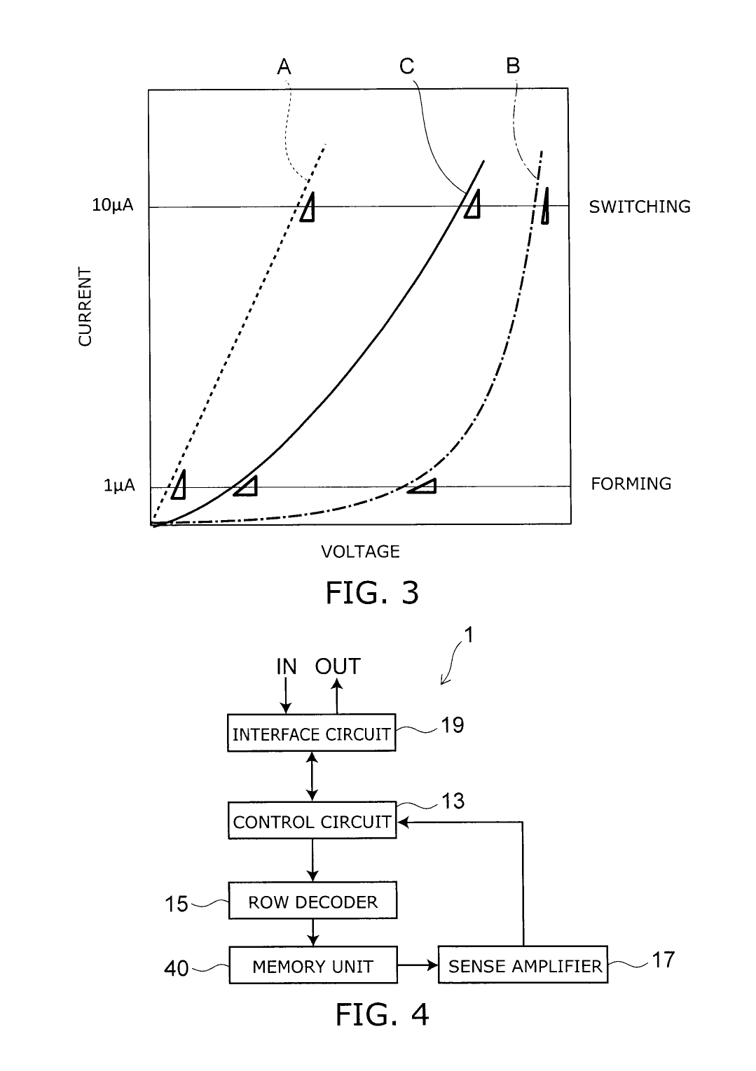

FIG. 3 is a graph illustrating I-V characteristics of respective materials, in which the horizontal axis indicates voltage and the vertical axis indicates current.

In FIG. 3, a broken line A indicates an I-V characteristic of a metal material. The I-V characteristic of the metal material has a high linearity, and the resistance value R_{1μA} and the resistance value R_{10μA} are almost equal to each other. However, the metal material has a low resistivity, and if the high resistance component 32 is formed of the metal material, the high resistance component 32 is required to be made thick in order to realize a required resistance value, and the aspect ratio of processing increases.

A one-dot-chain line B indicates an I-V characteristic of an insulating material. The I-V characteristic of the insulating material has a low linearity, and the value (R_{1μA}/R_{10μA}) of the ratio is 5 or more. If the high resistance component 32 is formed of the insulating material, since the resistance value R_{1μA} is very high, it is difficult to cause a required current to flow at the time of forming. If the high resistance component 32 is made thin to such a degree that the required current can flow at the time of forming, since the resistance value R_{10μA} is low, it is difficult to limit the current at the time of switching.

On the other hand, a solid line C indicates an I-V characteristic of a material for forming the high resistance component 32 in the embodiment. The value (R_{1μA}/R_{10μA}) of the ratio of the material is 1 or more and less than 5, and the resistivity when a current of 1 μA flows through the high resistance component 32 is higher than 0.01 Ω•cm. When the high resistance component 32 is formed of the material as stated above, a required current can be made to flow at the time of forming of the resistance change film 42, and a current can be limited at the time of switching.

Next, the whole configuration of the memory device of the embodiment will be described.

FIG. 4 is a block diagram illustrating the memory device of the embodiment.

As shown in FIG. 4, the memory device 1 is provided with a row decoder 15 to drive the local word lines 43 disposed in the memory unit 40 and a sense amplifier 17 connected to the global bit lines 10. The sense amplifier 17 determines data read from the memory cell 45 and temporally stores. Besides, the memory device 1 is provided with a control circuit 13 and an interface circuit 19. The control circuit 13 writes information in the memory cell 45 through the row decoder 15 and the sense amplifier 17 based on an instruction inputted from the outside through the interface circuit 19, and reads information from the memory cell 45.

Next, the operation of the embodiment will be described.

As shown in FIG. 1 and FIG. 4, the control circuit 13 selects one of the plural global bit lines 10 through the sense amplifier 17. Besides, the control circuit 13 applies a specified potential to the gate electrode 25 to control conduction of the semiconductor component 21, and selects one of the plural local bit lines 41 connected to the selected global bit line 10. Specifically, an on potential is applied to the gate electrodes 25 on both sides of the semiconductor component 21 provided between the selected global bit line 10 and the local bit line 41 to be selected, and the semiconductor component 21 is put into a conductive state. Besides, an off potential is applied to the other gate electrodes 25, and the other semiconductor components 21 are put into a non-conductive state. By this, the selected global bit line 10 is connected to only the one local bit line 41 to be selected.

Besides, the control circuit 13 selects one of the plural local word lines 43, and selects one memory cell 45 formed of the selected local bit line 41 and the selected local word line 43. By this, the current path including “the local word line 43—the resistance change film 42—the local bit line 41—the high resistance component 32—the semiconductor component 21—the global bit line 10” is formed.

For example, when information recorded in the memory cell 45 is read, the control circuit 13 applies a specified read voltage between the selected local word line 43 and the selected global bit line 10, and the sense amplifier 17 detects a current flowing through the selected global bit line 10. The information recorded in the memory cell 45 is specified based on the output from the sense amplifier 17, and this information is outputted through the interface circuit 19.

When information is written in the memory cell 45, or when information recorded in the memory cell is erased, a specified read/write or erase voltage is applied between the selected local word line 43 and the selected global bit line 10, and the memory cell 45 is caused to transition between a high resistance state and a low resistance state. At this time, since the high resistance component 32 is interposed in the current path, the current flowing to the memory cell 45 is limited, and breakage of the resistance change film 42 is prevented.

Further, also when forming is performed on the memory cell 45, one global bit line 10 is selected, one local bit line 41 is selected by applying an on potential to one gate electrode 25, and one local word line 43 is selected, so that the foregoing current path is conducted, one memory cell 45 is selected. A forming voltage is applied between the selected global bit line 10 and the selected local word line 43, so that a filament is formed in the resistance change film 42 belonging to the selected memory cell 45, and forming is performed on the memory cell 45.

Next, effects of the embodiment will be described.

In the embodiment, the high resistance component 32 is connected between the semiconductor component 21 and the local bit line 41. By this, the amount of current flowing through the memory cell 45 is limited, and the breakage of the resistance change film 42 and the like due to overcurrent can be prevented. As a result, the current of the memory device 1 is reduced, and the shrink can be realized.

If the high resistance component 32 is formed on the side surface of the local word line 43, the interval between the local bit lines 41 in the X-direction is enlarged. On the other hand, as in the embodiment, if the high resistance component 32 is disposed between the semiconductor component 21 and the local bit line 41, the position of the memory unit 40 merely shifts upward as a whole, and the interval between the local bit lines 41 in the X-direction is not required to be enlarged. Thus, high integration of the memory unit 40 is not prevented by the provision of the high resistance component 32. Besides, even if the high resistance component 32 is provided, the aspect ratio of processing of the local bit line 41 and the like hardly increases, and the difficulty of processing hardly increases. In order to form the high resistance components 32, a continuous film for the high resistance components 32 is formed, and has only to be divided into a matrix form. Thus, the high resistance components 32 can be easily formed.

According to the embodiment described above, the highly integrated memory device can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A memory device comprising:
a selection element;
a first interconnection provided in a first direction when viewed from the selection element and extending in the first direction;
a plurality of second interconnections provided in a second direction crossing the first direction when viewed from the first interconnection and arranged in the first direction;
a memory element provided between the first interconnection and the second interconnection; and
a high resistance component connected between the selection element and the first interconnection and having a resistivity higher than a resistivity of the first interconnection and a resistivity of the second interconnection.

2. The device according to claim 1, wherein
the resistivity of the high resistance component is higher than 0.01 Ω•cm, and
a value of a ratio of a resistance value obtained when a current of 1 μA flows to a resistance value obtained when a current of 10 μA flows through the high resistance component is 1 or more and less than 5.

3. The device according to claim 1, wherein the high resistance component includes at least one of a metal nitride and a metal oxide.

4. The device according to claim 1, wherein the high resistance component includes a tantalum silicon nitride.

5. The device according to claim 1, further comprising a barrier layer connected between the selection element and the high resistance component and having a resistivity lower than the resistivity of the high resistance component.

6. The device according to claim 1, further comprising a barrier layer connected between the first interconnection and the high resistance component and having a resistivity lower than the resistivity of the high resistance component.

7. The device according to claim 1, wherein the memory element is a resistance change film.

8. The device according to claim 1, wherein the second interconnection extends in a third direction, and the first direction, the second direction and the third direction are orthogonal to each other.

9. A memory device comprising:
a selection element;
a first interconnection provided in a first direction when viewed from the selection element and extending in the first direction;
a plurality of second interconnections provided in a second direction crossing the first direction when viewed from the first interconnection and arranged in the first direction;
a memory element provided between the first interconnection and the second interconnection; and
a high resistance component connected between the selection element and the first interconnection and including at least one of a metal nitride and a metal oxide.

10. The device according to claim 9, wherein the resistivity of the high resistance component is higher than 0.01 Ω•cm, and
a value of a ratio of a resistance value obtained when a current of 1 μA flows to a resistance value obtained when a current of 10 μA flows through the high resistance component is 1 or more and less than 5.

11. The device according to claim 9, wherein the high resistance component includes a tantalum silicon nitride.

12. The device according to claim 9, further comprising a barrier layer connected between the semiconductor component and the high resistance component and having a resistivity lower than the resistivity of the high resistance component.

13. The device according to claim 9, further comprising a barrier layer connected between the first interconnection and the high resistance component and having a resistivity lower than the resistivity of the high resistance component.

14. The device according to claim 9, wherein the memory element is a resistance change film.

15. The device according to claim 9, wherein the second interconnection extends in a third direction, and the first direction, the second direction and the third direction are orthogonal to each other.
